(19) United States
(12) Patent Application Publication
(10) Pub. No.: US 2026/0090332 A1
(43) Pub. Date: Mar. 26, 2026

(54) SUSCEPTOR FOR EPITAXIAL GROWTH AND METHOD FOR PRODUCING EPITAXIAL WAFER

(71) Applicant: Shin-Etsu Handotai Co., Ltd., Tokyo (JP)

(72) Inventor: Hayato NAGAI, Nishigo-mura (JP)

(73) Assignee: Shin-Etsu Handotai Co., Ltd., Tokyo (JP)

(21) Appl. No.: 19/112,794

(22) PCT Filed: Jul. 20, 2023
(86) PCT No.: PCT/JP2023/026488

§ 371 Date: Mar. 18, 2025

(30) Foreign Application Priority Data
Sep. 28, 2022 (JP) 2022-155446

(51) Int. Cl. H10P 72/76; C30B 25/12; C30B 25/18

(52) U.S. Cl. CPC H10P 72/7611; C30B 25/12; C30B 25/18

(57) ABSTRACT

The present invention is a susceptor for epitaxial growth on a wafer having a main surface of a (110) plane, the susceptor for epitaxial growth including: a pocket for mounting a wafer; and an outer periphery surrounding the pocket, wherein the outer periphery is provided with a flat portion and a raised portion that is a portion adjacent to the pocket and that has a portion projected from an upper face of the flat portion, and the pocket is designed such that, when the wafer is mounted on the pocket, a height of an upper face of the wafer is positioned above a height of the upper face of the flat portion. This provides a susceptor for epitaxial growth that can produce a highly flat (110) epitaxial wafer by using a wafer (a substrate) having a main surface of (110).

### TECHNICAL FIELD

The present invention relates to a susceptor for epitaxial growth and a method for producing an epitaxial wafer.

### BACKGROUND ART

With miniaturization of circuit line width of semiconductor devices in recent years, a wafer having high flatness to the outermost peripheral region as a wafer for the latest device has been required.

Epitaxial wafers having a main surface of (100) have been used, and developed is a susceptor mainly for the wafer having the (100) plane as described in Patent Document 1. Meanwhile, a large-diameter epitaxial wafer having a main surface of other than (100), as described in Patent Document 2, has been recently required because of properties of the device. However, a local growth speed in the outermost peripheral region is affected and changes by an adjacent orientation, and thus, the design of the susceptor according to the main surface has been required.

### CITATION LIST

### Patent Literature

Patent Document 1: JP 2010-40534 A
Patent Document 2: JP 2021-34410 A

### SUMMARY OF INVENTION

### Technical Problem

For the recent latest devices, requirement of an epitaxial wafer having a main surface of (110) has increased, and highly flattening has become important. However, since the crystal orientation is different from that of the (100) wafer, it is difficult to simultaneously flatten a plurality of indices of wafer flatness, such as ESFOR MAX and Front ZDD, even using a susceptor developed for (100).

Patent Document 1 proposes a susceptor characterized in that a depressed portion (a pocket) to contain a wafer is deeper than a wafer thickness and in that a projected portion is provided on a side wall. Raising the side wall typically causes process gas to be hardly supplied to the outermost periphery of the wafer to inhibit vapor-phase growth. Thus, an epi-film thickness decreases toward the outer periphery, and Front ZDD, which is one of indices of the flatness, shifts to be a negative side. Here, since the Front ZDD of the (110) wafer easily becomes negative compared with the (100) epi-wafer, depression of the outer periphery becomes large when the above proposed susceptor is used, and it is difficult to improve the Front ZDD even when the projected portion is adjusted for (110).

Patent Document 2 specifically mentions a susceptor for a main surface of a (111) plane. However, this susceptor also has different locations with a high growth speed and a low growth speed on the outermost periphery, and it is difficult to flatten ESFOR.

The present invention has been made to solve the above problem. An object of the present invention is to provide a susceptor for epitaxial growth and a method for producing an epitaxial wafer that can produce a highly flat (110) epitaxial wafer by using a wafer (a substrate) having a main surface of (110).

### Solution to Problem

The present invention has been made to achieve the above object. The present invention provides a susceptor for epitaxial growth on a wafer having a main surface of a (110) plane, the susceptor for epitaxial growth including: a pocket for mounting a wafer; and an outer periphery surrounding the pocket, wherein the outer periphery is provided with a flat portion and a raised portion that is a portion adjacent to the pocket and that has a portion projected from an upper face of the flat portion, and the pocket is designed such that, when the wafer is mounted on the pocket, a height of an upper face of the wafer is positioned above a height of the upper face of the flat portion.

With the susceptor for epitaxial growth as above, the highly flat (110) epitaxial wafer can be produced by using the wafer having a main surface of (110).

In this case, the outer periphery may be provided with a depressed portion that is a portion adjacent to the pocket and that has a portion depressed from the upper face of the flat portion.

This can more certainly produce the highly flat (110) epitaxial wafer by using the wafer having a main surface of (110).

In this case, when the wafer is mounted on the pocket, a pocket height from a position of a lower face of the wafer to the upper face of the flat portion may be a half or more of a thickness of the wafer.

This can more certainly produce the highly flat (110) epitaxial wafer by using the wafer having a main surface of (110).

In this case, when the wafer is mounted on the pocket, a difference between a pocket height from a position of a lower face of the wafer to the upper face of the flat portion and a thickness of the wafer may be 0.30 mm or less.

This can more certainly produce the highly flat (110) epitaxial wafer by using the wafer having a main surface of (110).

In this case, when the wafer is mounted on the pocket, a pocket height from a position of a lower face of the wafer to a lower end of the depressed portion may be a half or more of a thickness of the wafer.

This can more certainly produce the highly flat (110) epitaxial wafer by using the wafer having a main surface of (110).

In this case, when the wafer is mounted on the pocket, a difference between a pocket height from a position of a lower face of the wafer to a lower end of the depressed portion and a thickness of the wafer may be 0.30 mm or less.

This can more certainly produce the highly flat (110) epitaxial wafer by using the wafer having a main surface of (110).

The present invention has been made to achieve the above object. The present invention provides a method for producing an epitaxial wafer using the aforementioned susceptor for epitaxial growth to grow an epitaxial layer in a vapor phase on a wafer surface having a main surface of a (110) plane, the method including a step of: mounting a wafer on the pocket of the susceptor for epitaxial growth; arranging the wafer so that a direction of a {111} plane adjacent to the (110) plane of the surface of the wafer faces the raised portion; and then performing vapor-phase growth.

By the method for producing an epitaxial wafer as above, the highly flat (110) epitaxial wafer can be produced by using the wafer having a main surface of (110).

### Advantageous Effects of Invention

As above, according to the susceptor for epitaxial growth of the present invention, the highly flat (110) epitaxial wafer can be produced by using the wafer having a main surface of (110).

According to the method for producing an epitaxial wafer of the present invention, the highly flat (110) epitaxial wafer can be produced by using the wafer having a main surface of (110).

### BRIEF DESCRIPTION OF DRAWINGS

FIG. 1(a) is a plan view of the susceptor for epitaxial growth according to an embodiment of the present invention, and FIG. 1(b) is a sectional view thereof along the A-A line;

FIG. 2 is a schematic view illustrating a relationship of height between susceptor of Example 1 and a wafer;

FIG. 3 is a schematic view illustrating a raised portion in the susceptor of Example 1 viewed from a center side;

FIG. 4 is a schematic view of a wafer used for epitaxial growth in a case of an orientation (001) notch adjacent to a wafer surface;

FIG. 5 is a schematic view illustrating a relationship of height between a susceptor of Comparative Example 1 and a wafer;

FIG. 6 is a schematic view illustrating the susceptor of Comparative Example 1 viewed from a center side; and

FIG. 7 is a schematic view illustrating a relationship of height between a susceptor of Example 2 and a wafer.

### DESCRIPTION OF EMBODIMENTS

Hereinafter, the present invention will be described in detail, but the present invention is not limited thereto.

As noted above, there has been a demand for a susceptor for epitaxial growth and a method for producing an epitaxial wafer that can produce a highly flat (110) epitaxial wafer by using a wafer having a main surface of (110).

The present inventor has earnestly studied the above problem, and consequently found that the highly flat (110) epitaxial wafer can be produced by using the wafer having a main surface of (110) with a susceptor for epitaxial growth on a wafer having a main surface of a (110) plane, the susceptor for epitaxial growth including: a pocket for mounting a wafer; and an outer periphery surrounding the pocket, wherein the outer periphery is provided with a flat portion and a raised portion that is a portion adjacent to the pocket and that has a portion projected from an upper face of the flat portion, and the pocket is designed such that, when the wafer is mounted on the pocket, a height of an upper face of the wafer is positioned above a height of the upper face of the flat portion. This finding has led to completion of the present invention.

Hereinafter, the susceptor for epitaxial growth and the method for producing an epitaxial wafer according to embodiments of the present invention will be described.

### Susceptor for Epitaxial Growth

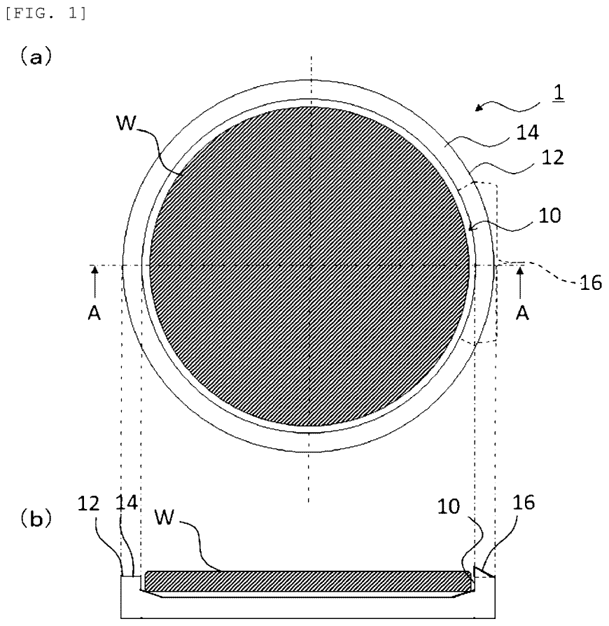

FIG. 1(a) is a plan view of the susceptor for epitaxial growth according to an embodiment of the present invention. FIG. 1(b) is a sectional view of the susceptor for epitaxial growth according to an embodiment of the present invention.

As illustrated in FIGS. 1(a) and (b), a susceptor 1 for epitaxial growth according to an embodiment of the present invention has a pocket 10 for mounting a wafer W and an outer periphery 12 surrounding the pocket 10.

The outer periphery 12 is provided with a flat portion 14 and a raised portion 16 that is a portion adjacent to the pocket 10 and that has a portion projected from an upper face of the flat portion 14.

For the pocket 10 having a concave shape for mounting the wafer W, the raised portion 16 is provided at least in a part of a direction in which a {111} plane is present when the wafer W is mounted.

Since the direction on the {111} plane yields a locally high growth speed, the growth speed can be reduced by the raised portion.

The pocket 10 is designed such that, when the wafer W is mounted on the pocket 10, a height of an upper face of the wafer W is positioned above a height of the upper face of the flat portion 14 (an upper face of the wafer W is projected from the flat portion 14).

At least a part of the direction in which the plane is present is designed such that, when the wafer W is mounted, the surface of the wafer W is higher than a side face of the pocket.

The {100} direction yields a relatively slow growth speed, tends to cause depression toward the outer periphery, and has a strong effect of shifting the Front ZDD onto the negative side. Thus, setting the wafer surface to be higher than the height of the side face of the pocket can reduce the shift of the Front ZDD onto the negative side due to the depression on the outer periphery.

The susceptor for epitaxial growth according to an embodiment of the present invention is provided with a through hole (illustration is omitted) for providing a lift pin for raising and lowering the wafer W, in addition to the pocket 10 for mounting the wafer W, and the wafer W is to be mounted on the pocket 10 by a carrying mechanism and raising and lowering the lift pin.

The pocket 10 may be provided with a shape to inhibit deposition on the back surface side, a through hole to inhibit automatic doping, etc.

When the wafer W is mounted on the pocket 10, a pocket height from a position of a lower face of the wafer W to the upper face of the flat portion 14 is preferably a half or more of a thickness of the wafer W. An upper limit of this pocket height is not particularly limited, and less than the thickness of the wafer W, for example. In addition, when the wafer W is mounted on the pocket 10, a difference between the pocket height from the position of the lower face of the wafer W to the upper face of the flat portion 14 and the thickness of the wafer W is more preferably 0.30 mm or less. A lower limit of this difference in thickness is not particularly limited, and more than 0 mm, for example. The positional relationship of height as above can provide higher flatness of the epitaxial wafer.

If the height of the pocket side face is excessively low, process gas tends to flow around to the wafer back surface to deteriorate quality of the wafer back surface.

The outer periphery 12 is preferably provided with a depressed portion that is a portion adjacent to the pocket 10 and that has a portion depressed from the upper face of the flat portion.

Providing the locally depressed portion in the direction corresponding to the {100} direction of the pocket 10 can increase the growth speed in this portion to more effectively inhibit the shift of the Front ZDD onto the negative side.

When the wafer W is mounted on the pocket 10, a pocket height from a position of a lower face of the wafer W to a lower end of the depressed portion is preferably a half or more of a thickness of the wafer W. An upper limit of this pocket height is not particularly limited, and less than the thickness of the wafer W, for example. In addition, when the wafer W is mounted on the pocket 10, a difference between the pocket height from the position of the lower face of the wafer W to the lower end of the depressed portion and the thickness of the wafer W is more preferably 0.30 mm or less. A lower limit of the difference in thickness is not particularly limited, and more than 0 mm, for example.

If the height of the pocket side face is excessively low, process gas tends to flow around to the wafer back surface to deteriorate quality of the wafer back surface.

### Method for Producing Epitaxial Wafer

Next, the method for producing an epitaxial wafer according to an embodiment of the present invention will be described.

The method for producing an epitaxial wafer according to an embodiment of the present invention is a method for producing an epitaxial wafer using the susceptor 1 for epitaxial growth to grow an epitaxial layer in a vapor phase on a wafer surface.

The method for producing an epitaxial wafer includes a step of: mounting a wafer W on the pocket 10 of the susceptor 1 for epitaxial growth; arranging the wafer W so that a direction of a {111} plane adjacent to the (110) plane of the surface of the wafer W faces the raised portion 16; and then performing vapor-phase growth.

The growth speed in the direction of the {111} plane can be reduced by the raised portion, and the shift of the Front ZDD onto the negative side due to depression of the outer periphery caused by the slow growth speed in the {100} direction can be inhibited by setting the wafer surface to be higher than the height of the pocket side face. Therefore, the highly flat (110) epitaxial wafer can be produced by using the wafer having a main surface of (110).

### EXAMPLE

Hereinafter, the present invention will be specifically described with Examples, but these Examples do not limit the present invention.

### Example 1

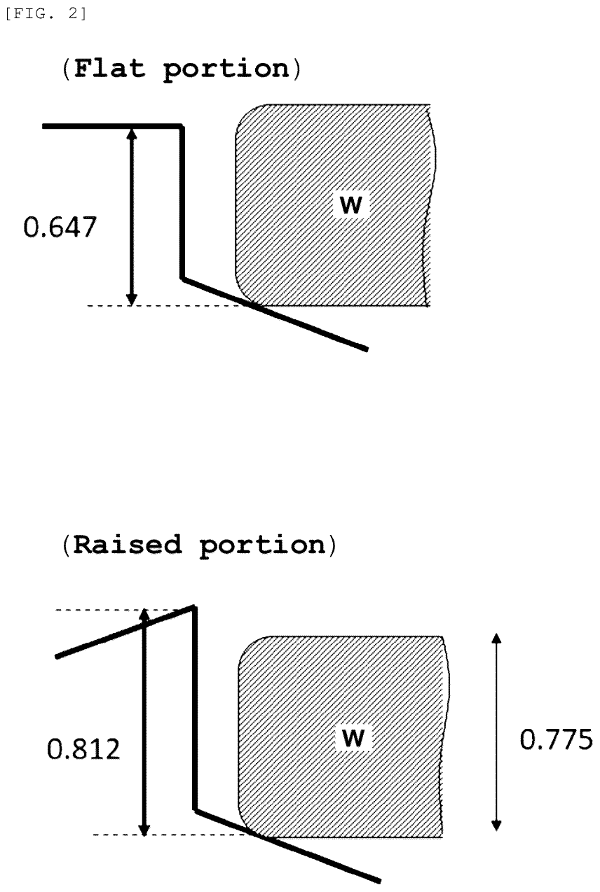

FIG. 2 is a schematic view illustrating a relationship of height between a susceptor of Example 1 and a wafer.

First, prepared was the susceptor of Example 1 designed such that a height of a flat portion was 0.647 mm and a maximum height of a raised portion was 0.812 mm.

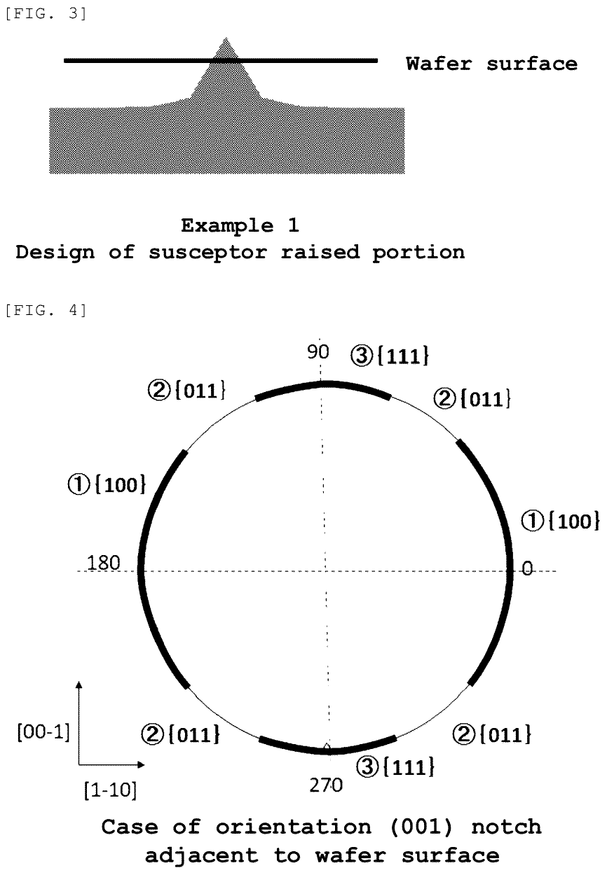

FIG. 3 is a schematic view illustrating the raised portion in the susceptor of Example 1 viewed from the center side.

This raised portion was provided such that the height increased toward the highest imaginary position at the center in the circumferential direction within a range of +40° from the highest imaginary position at the center.

FIG. 4 is a schematic view of a wafer used for epitaxial growth in a case of an orientation (001) notch adjacent to a wafer surface.

The wafer used for the epitaxial growth had a main surface of (110) and had a thickness of 0.775±0.01 mm.

When the wafer was mounted on the susceptor, the pocket portion of the flat portion was lower than the wafer surface. The wafer was arranged such that a direction of a {111} plane of the (110) wafer faced the raised portion of the susceptor.

As above, the susceptor of the present invention was attached to the chamber, and epitaxial growth was performed on the wafer having the main surface of (110) washed in advance to produce a sample of Example 1. Then, the quality was evaluated by a flatness measurement.

### Comparative Example 1

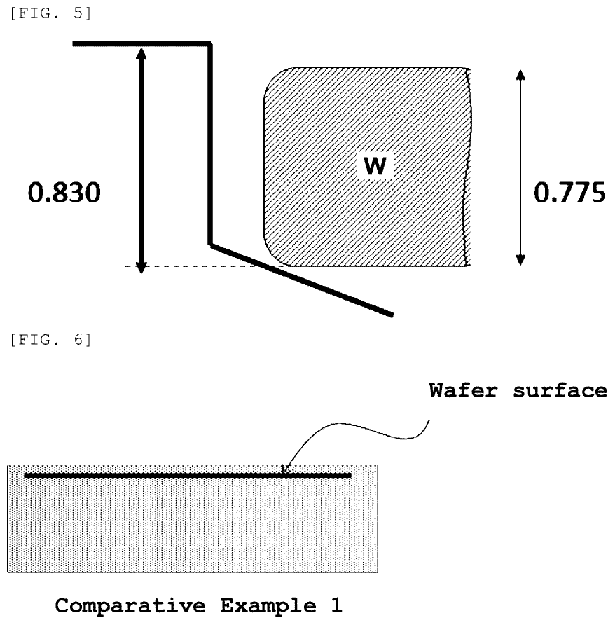

FIG. 5 is a schematic view illustrating a relationship of height between a susceptor of Comparative Example 1 and a wafer.

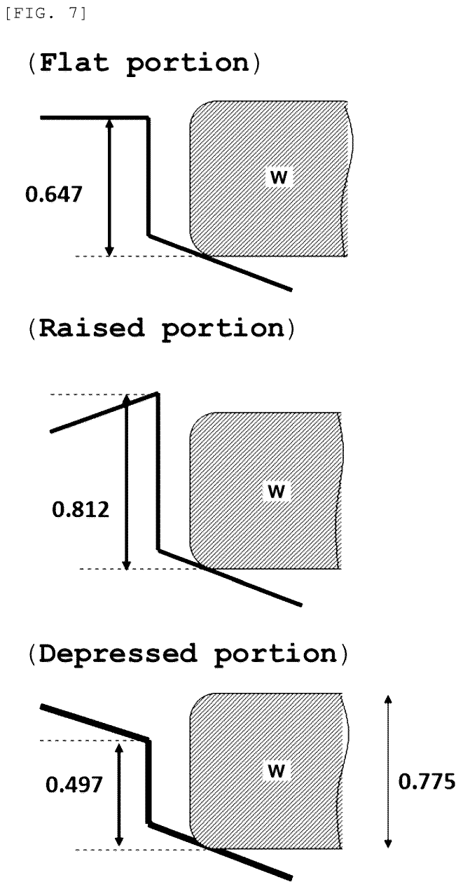

FIG. 6 is a schematic view illustrating the susceptor of Comparative Example 1 viewed from a center side.

Prepared was a susceptor of Comparative Example 1 having no raised portion in the outer periphery, and designed such that, when the wafer was mounted in the pocket, the pocket height was 0.830 mm in the entirety of the peripheral direction.

The wafer to react had a main surface of (110) and a thickness of 0.775±0.01 mm. The wafer surface was lower than the pocket portion in the entire periphery when the wafer was mounted on the susceptor.

This susceptor was attached to the chamber, and epitaxial growth was performed on the wafer having the main surface of (110) washed in advance to produce a sample of Comparative Example 1. Then, the quality was evaluated by a flatness measurement.

As a result of the quality evaluation, the sample of Comparative Example 1 exhibited ESFOR MAX, which was an index of flatness on the outer periphery, of 0.022 μm in average, and in contrast, that of the sample of Example 1 was 0. 018 μm, which was confirmed to be 18% of the improvement effect. As for the Front ZDD, the sample of Comparative Example 1 was −25.7 nm/mm², and in contrast, the sample of Example 1 was −14.9 nm/mm², which yielded the effect of shifting about 10 nm/mm² onto the positive side.

### Example 2

FIG. 7 is a schematic view illustrating a relationship of height between a susceptor of Example 2 and a wafer.

First, prepared was a susceptor of Example 2 designed such that a height of the flat portion was 0.647 mm, a maximum height of the raised portion was 0.812 mm, and so as to have a depressed portion with a lower end having a height of 0.497 mm.

This susceptor was attached to the chamber, and epitaxial growth was performed on the wafer having the main surface of (110) washed in advance to produce a Sample of Example 2. Then, the quality was evaluated by a flatness measurement. In this time, the wafer was arranged so that the {111} plane direction of the (110) wafer faced the raised portion and so that the {100} plane direction of the (110) wafer faced the depressed portion.

As a result of the quality evaluation, the sample of Example 2 exhibited ESFOR MAX, which was an index of flatness on the outer periphery, of 0.016 μm, which was confirmed to be the improvement effect. As for the Front ZDD, the sample of Example 2 was −12.9 nm/mm², which yielded the effect of shifting onto the positive side.

The present description includes the following embodiments.
[1]: A susceptor for epitaxial growth on a wafer having a main surface of a (110) plane, the susceptor for epitaxial growth comprising:
a pocket for mounting a wafer; and
an outer periphery surrounding the pocket, wherein
the outer periphery is provided with a flat portion and a raised portion that is a portion adjacent to the pocket and that has a portion projected from an upper face of the flat portion, and
the pocket is designed such that, when the wafer is mounted on the pocket, a height of an upper face of the wafer is positioned above a height of the upper face of the flat portion.
[2]: The susceptor for epitaxial growth according to the above [1], wherein the outer periphery is provided with a depressed portion that is a portion adjacent to the pocket and that has a portion depressed from the upper face of the flat portion.
[3]: The susceptor for epitaxial growth according to the above [1] or [2], wherein, when the wafer is mounted on the pocket, a pocket height from a position of a lower face of the wafer to the upper face of the flat portion is a half or more of a thickness of the wafer.
[4]: The susceptor for epitaxial growth according to any one of the above [1] to [3], wherein, when the wafer is mounted on the pocket, a difference between a pocket height from a position of a lower face of the wafer to the upper face of the flat portion and a thickness of the wafer is 0.30 mm or less.
[5]: The susceptor for epitaxial growth according to the above [2], wherein, when the wafer is mounted on the pocket, a pocket height from a position of a lower face of the wafer to a lower end of the depressed portion is a half or more of a thickness of the wafer.
[6]: The susceptor for epitaxial growth according to the above [2], wherein, when the wafer is mounted on the pocket, a difference between a pocket height from a position of a lower face of the wafer to a lower end of the depressed portion and a thickness of the wafer is 0.30 mm or less.
[7]: A method for producing an epitaxial wafer using the susceptor for epitaxial growth according to any one of the above [1] to [6] to grow an epitaxial layer in a vapor phase on a wafer surface having a main surface of a (110) plane, the method comprising a step of:
mounting a wafer on the pocket of the susceptor for epitaxial growth;
arranging the wafer so that a direction of a {111} plane adjacent to the (110) plane of the surface of the wafer faces the raised portion; and then
performing vapor-phase growth.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A susceptor for epitaxial growth on a wafer having a main surface of a (110) plane, the susceptor for epitaxial growth comprising:
a pocket for mounting a wafer; and
an outer periphery surrounding the pocket, wherein
the outer periphery is provided with a flat portion and a raised portion that is a portion adjacent to the pocket and that has a portion projected from an upper face of the flat portion, and
the pocket is designed such that, when the wafer is mounted on the pocket, a height of an upper face of the wafer is positioned above a height of the upper face of the flat portion.

2. The susceptor for epitaxial growth according to claim 1, wherein the outer periphery is provided with a depressed portion that is a portion adjacent to the pocket and that has a portion depressed from the upper face of the flat portion.

3. The susceptor for epitaxial growth according to claim 1, wherein, when the wafer is mounted on the pocket, a pocket height from a position of a lower face of the wafer to the upper face of the flat portion is a half or more of a thickness of the wafer.

4. The susceptor for epitaxial growth according to claim 1, wherein, when the wafer is mounted on the pocket, a difference between a pocket height from a position of a lower face of the wafer to the upper face of the flat portion and a thickness of the wafer is 0.30 mm or less.

5. The susceptor for epitaxial growth according to claim 2, wherein, when the wafer is mounted on the pocket, a pocket height from a position of a lower face of the wafer to a lower end of the depressed portion is a half or more of a thickness of the wafer.

6. The susceptor for epitaxial growth according to claim 2, wherein, when the wafer is mounted on the pocket, a difference between a pocket height from a position of a lower face of the wafer to a lower end of the depressed portion and a thickness of the wafer is 0.30 mm or less.

7. A method for producing an epitaxial wafer using the susceptor for epitaxial growth according to claim 1 to grow an epitaxial layer in a vapor phase on a wafer surface having a main surface of a (110) plane, the method comprising a step of:
mounting a wafer on the pocket of the susceptor for epitaxial growth;
arranging the wafer so that a direction of a {111} plane adjacent to the (110) plane of the surface of the wafer faces the raised portion; and then
performing vapor-phase growth.
